(19) United States
(12) Patent Application Publication
(10) Pub. No.: US 2006/0083085 A1
(43) Pub. Date: Apr. 20, 2006

(54) Integrated circuit device and testing method thereof

(75) Inventor: Junichi Ikegami, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 11/240,767

(22) Filed: Oct. 3, 2005

(30) Foreign Application Priority Data
Oct. 4, 2004 (JP) 2004-291119

(51) Int. Cl. G11C 29/00

(52) U.S. Cl. 365/200

(57) ABSTRACT

An integrated circuit device has a plurality of memory macros that include a redundant circuit to replace a defective cell and a plurality of bits of nonvolatile memory elements that store redundant replacement information to replace a defective cell of a first memory macro selected from the plurality of memory macros with the redundant circuit. The redundant replacement information is transferred with a plurality of bits in parallel from the plurality of bits of nonvolatile memory elements to the plurality of memory macros.

### BACKGROUND OF THE INVENTION

1. Field of the Invention

The present invention relates to an integrated circuit device and a testing method of the same and, particularly, to an integrated circuit device having a redundant circuit and a testing method of the same.

2. Description of Related Art

With the recent rapid development of small-sized and multifunction electronic devices, the need for more highly integrated circuit devices is increasing. A system LSI or SOC (System On a Chip) technology that integrates a plurality of functions into one semiconductor chip is known as a highly integrated circuit device. Integrated circuit devices such as a system LSI go through tests to check the presence of a manufacturing defect in order to ensure reliability so that only nondefective products that have passed the tests are shipped. For example, if a defect is found on a memory test, a defective part is replaced with a redundant circuit to save the defective part.

FIG. 10 shows a conventional integrated circuit device. The integrated circuit device 101 is a system LSI that includes a plurality of memory macros 103 for various functions and applications and a plurality of fuse boxes 102 for saving defective cells of the memory macros 103.

Each memory macro 103 includes memory cells and redundant circuits, though not shown. A defective cell in the memory cells is replaced with the redundant circuit, thereby saving the defective cell.

Each fuse box 102 has a plurality of fuses and stores desired data according to the cutting states of the fuses. The fuse box 102 stores an address that specifies a defective cell in the memory cells, which is referred to hereinafter as the defective address. The defective address is transferred to the memory macro 103, and the corresponding defective cell is replaced with the redundant circuit.

The conventional integrated circuit device 101 needs to have the same number of fuse boxes 102 as the memory macros 103 since all the memory macros 103 and all the fuse boxes 102 are respectively connected one to one. Due to the physical size of a fuse body required for laser cutting or overcurrent fusing and the structure of a fuse that requires some space around it to avoid adverse impacts on the vicinity of a cut portion, it is difficult to reduce the size of fuses even if semiconductor process miniaturization advances. Therefore, as miniaturization and high integration of integrated circuit devices progress, the proportion of the fuse circuit area in an integrated circuit device increases accordingly. Particularly, since the system LSI has a number of memory macros with small memory capacities compared to a general-purpose memory chip, it requires a large number of fuse boxes 102, making the fuse circuit area extremely large.

An integrated circuit device to overcome the above problem is disclosed in Japanese Unexamined Patent Publication No. 2004-133970. This integrated circuit device reduces the number of fuses by compressing redundant replacement information such as defective addresses.

However, this technique compresses and decompresses data when transferring redundant replacement information from a fuse box to a memory macro and, further, transfers data serially. The integrated circuit device therefore needs to have a complex compressor/decompressor, data analyzer and so on and it takes a long time to transfer data. If an input/output circuit for data transfer is complex, it requires a large circuit area and also requires redesigning a compressor/decompressor, data analyzer and so on when changing the number of memory macros, thus causing low extensibility and large design man-hours.

As described in the foregoing, it has been discovered that the conventional integrated circuit device has the problem that reducing the number of nonvolatile memory circuits that store redundant replacement information with respect to the number of memory macros complicates an input/output circuit that transfers the redundant replacement information.

### SUMMARY OF THE INVENTION

According to an aspect of the present invention, there is provided an integrated circuit device that includes a plurality of memory macros each of which including a redundant circuit to replace a defective cell and a plurality of bits of nonvolatile memory elements storing redundant replacement information to replace a defective cell of a first memory macro selected from the plurality of memory macros with the redundant circuit, wherein the redundant replacement information is transferred with a plurality of bits in parallel from the plurality of bits of nonvolatile memory elements to the plurality of memory macros.

Since the integrated circuit device of the present invention stores redundant replacement information of a memory macro selected from a plurality of memory macros into a plurality of bits of nonvolatile memory elements (for example, fuse boxes), it is possible to reduce the number of nonvolatile memory elements. Further, since it transfers redundant replacement information with a plurality of bits in parallel, it is possible to transfer the redundant replacement information as it is without any processing. This allows simplifying an input/output circuit for transferring the redundant replacement information.

According to another aspect of the present invention, there is provided a testing method of an integrated circuit device having a memory macro, a test circuit, and a fuse box, that includes testing the memory macro by the test circuit, storing redundant replacement information containing memory macro identification information for identifying the memory macro and a defective address for identifying a defective cell of the memory macro into the fuse box according to a test result, and replacing the defective cell of the memory macro with a redundant circuit according to the redundant replacement information. This method allows efficient testing on the memory macro.

The present invention provides an integrated circuit device with the reduced number of nonvolatile memory circuits to store redundant replacement information with respect to the number of memory macros and a simplified input/output circuit to transfer redundant replacement information.

### BRIEF DESCRIPTION OF THE DRAWINGS

The above and other objects, advantages and features of the present invention will be more apparent from the following description taken in conjunction with the accompanying drawings, in which:

FIG. 1 is a block diagram showing the configuration of an integrated circuit device according to the present invention;

FIG. 2 is a block diagram showing the configuration of a fuse box according to the present invention;

FIG. 3 is a view showing the data structure of redundant replacement information according to the present invention;

FIG. 4 is a block diagram showing the configuration of a memory macro according to the present invention;

FIG. 5 is a block diagram showing the configuration of a memory macro according to the present invention;

FIG. 6 is a block diagram showing the configuration of an integrated circuit device according to the present invention;

FIG. 7 is a view showing the data structure of fuse cutting information according to the present invention;

FIG. 8 is a block diagram showing the configuration of an integrated circuit device according to the present invention;

FIG. 9 is a flowchart showing a testing method of an integrated circuit device according to the present invention; and

FIG. 10 is a block diagram showing the configuration of a conventional integrated circuit device.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Embodiment

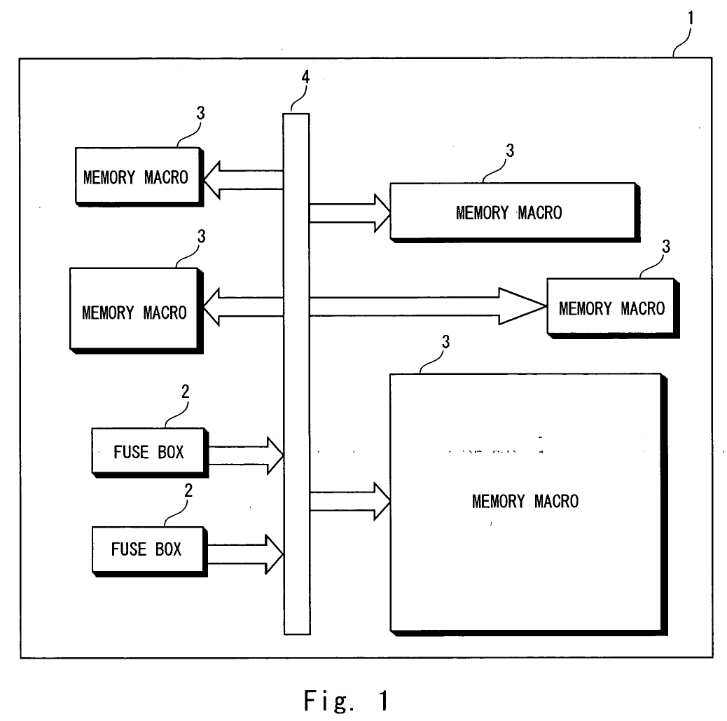

An integrated circuit device according to a first embodiment of the present invention is described hereinafter with reference to FIGS. 1 to 5. The integrated circuit device of this embodiment has a smaller number of fuse boxes than memory macros and transfers redundant replacement information at a time.

Referring first to FIG. 1, the configuration of the integrated circuit device of this embodiment is described herein. The integrated circuit device 1 has a plurality of fuse boxes 2 and a plurality of memory macros 3, and each fuse box 2 and each memory macro 3 are connected through a fuse bus 4.

The integrated circuit device 1 is a system LSI with a plurality of functions, for example. It has a CPU core, a peripheral module such as DSP (Digital Signal Processor) and so on, though not shown. The CPU core, peripheral module and so on perform desired processing with the data stored in the memory macros 3.

The fuse box 2 is a nonvolatile memory circuit that has a plurality of bits of nonvolatile memory elements and stores redundant replacement information of one of the plurality of memory macros 3. The redundant replacement information is a plurality of bits of information and contains macro ID for specifying a memory macro to transmit a defective address and an address of a defective cell (defective address) in the specified memory macro as detailed later. For example, the fuse box 2 has a plurality of fuses as nonvolatile memory elements and stores redundant replacement information according to the cutting states of the fuses. The redundant replacement information stored in the fuse box 2 is transferred from the fuse box 2 to the memory macro 3 by a control signal of the CPU core upon initialization of the integrated circuit device 1, for example.

The memory macro 3 is a memory circuit and has a redundant circuit to replace a defective cell according to the redundant replacement information of the fuse box 2. The memory macro 3 stores the data required for the operation of the CPU core, peripheral module and so on. The memory macro 3 may be RAM such as DRAM (Dynamic Random Access Memory) and SRAM (Static Random Access Memory), for example. It may be another circuit as long as it is replaceable with a redundant circuit.

A plurality of memory macros 3 are placed for different applications, for example, and a macro ID is set to identify each memory macro 3. For example, the memory macros 3 may involve main memory, cache memory for instruction storage, cache memory for data storage and so on if it is memory for the CPU core. Further, the memory macros 3 have different capacities according to their applications. The capacity of the memory macro 3 is defined by a memory cell included therein. For example, one memory macro 3 includes a memory cell having a 4 K-bit capacity organized as 512 words by 8 bits, and another memory macro 3 has a 512 K-bit capacity organized as 4 K words by 128 bits.

Though FIG. 1 shows five memory macros 3 and two fuse boxes 2, the number of memory macros 3 and fuse boxes 2 may be arbitrary. It is preferred that the number of fuse boxes 2 is smaller than the number of memory macros 3. The smaller the number of fuse boxes 2 is, the smaller the number of fuses is, thus reducing the circuit area.

Generally, a system LSI has a very large number of memory macros 3 with small capacities compared to a general-purpose memory chip. For example, it has several dozen of 1 K-bit memory macros 3 and the total capacity of all the memory macros 3 is several M bits. In such a configuration, since the capacity of each memory macro 3 is small, the probability that a defect occurs in each memory macro 3 is low, and a large number of memory macros 3 without any defect exist. Therefore, in this embodiment, the number of fuse boxes 2 (or the number of pieces of redundant replacement information) depends on the entire proportion defective of the memory macros 3 and it is smaller than the number of memory macros 3. Thus, the number of fuse boxes 2 is preferably not equal to the number of all the memory macros 3 but equal to the number of the memory macros 3 where a defect can occur with respect to the total capacity of all the memory macros 3. This allows reducing the number of fuse boxes 2 to a required minimum number. For example, three or four fuse boxes 2 may be placed for several dozen of memory macros 3.

The fuse bus 4 transfers a plurality of bits of redundant replacement information in parallel that is stored in the fuse box 2 to the memory macros 3. The fuse bus 4 preferably has a bus width that allows parallel transfer of all the bits of the redundant replacement information. For example, the redundant replacement information output from the fuse box 2 is transferred to all the memory macros 3 through the fuse bus 4 at the same timing.

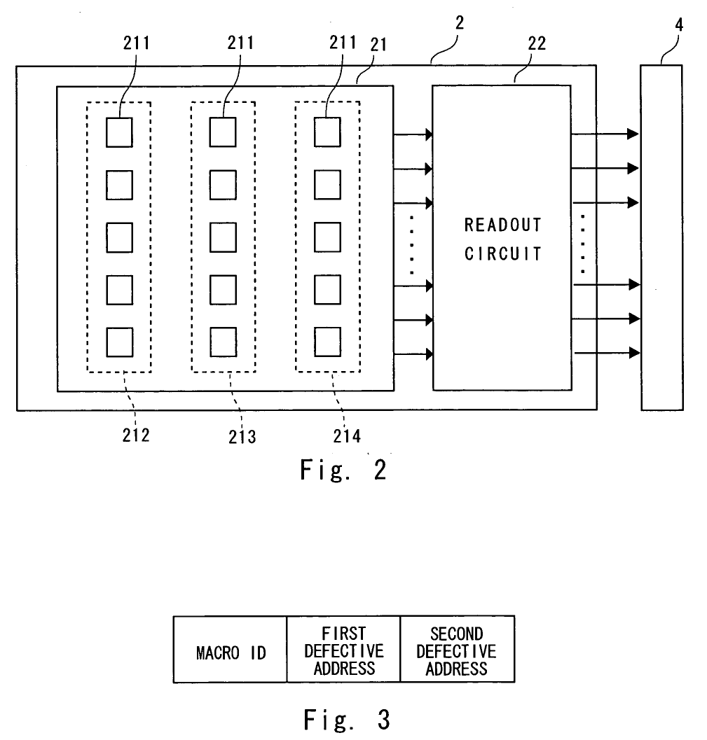

Referring next to FIG. 2, the configuration of the fuse box according to this embodiment is described herein. The fuse box 2 has a fuse set 21 and a readout circuit 22.

The fuse set 21 includes a plurality of fuses 211 to store redundant replacement information. Each fuse 211 may be an optical fuse to be cut by a laser beam or an electric fuse to be cut by a large current or voltage.

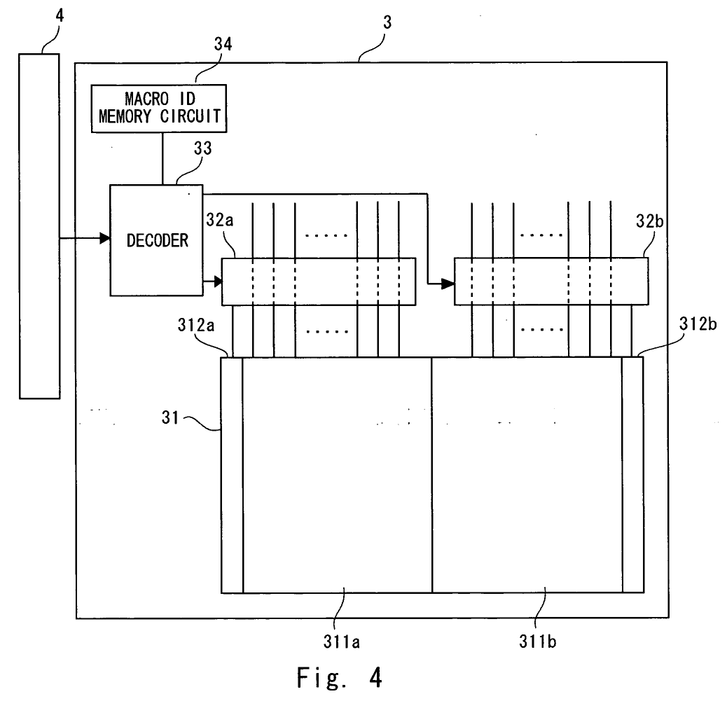

The fuses 211 are divided into a group for storing a macro ID of the memory macro 3 and a group for storing defective addresses of the memory macros 3 according to the data of redundant replacement information to store. For example, they are divided into a fuse line 212 to store a macro ID of the memory macro 3, a fuse line 213 to store a first defective address of the memory macro 3, and a fuse line 214 to store a second defective address of the memory macro 3. The memory cell of the memory macro 3 has two regions as shown in FIG. 4. A defective address in a first region (memory core 311a) is the first defective address and a defective address in a second region (memory core 311b) is the second defective address.

For example, one fuse 211 stores 1-bit data according to its cutting state. It indicates “0” if the fuse is not cut and it indicate “1” if the fuse is cut, for example. In the example of FIG. 2, each of the fuse lines 212, 213 and 214 includes five fuses 211 and can store 5-bit data, representing one of data 0 to 31. Thus, the fuse line 212 can store selected one of 32 macro IDs, the fuse line 213 can store selected one of 32 first defective addresses, and the fuse line 214 can store selected one of 32 second defective addresses.

The fuses 211 are not necessarily arranged as shown in FIG. 2 but may be arranged arbitrarily. For example, the fuses 211 may be arranged so as to easily output redundant replacement information in parallel to the fuse bus 4 through the readout circuit 22, and they may be arranged in one line.

The redundant replacement information that is stored in the fuse set 21 is composed of macro ID, a first defective address and a second defective address as shown in FIG. 3, for example, and if each has 5 bits, it is 15-bit data in total. In this embodiment, one piece of redundant replacement information contains one macro ID and all defective addresses of the corresponding memory macro 3. One memory macro 3 is associated with one piece of redundant replacement information, and one fuse box 2 stores one piece of redundant replacement information.

The readout circuit 22 of FIG. 2 serves both as a readout circuit to read redundant replacement information from the fuse set 21 and an output circuit to output redundant replacement information in parallel to the memory macro 3. For example, the readout circuit 22 supplies current to each fuse 211 and recognizes “0” or “1” of stored data by the voltage of a connection node with the fuse 211, thereby reading out redundant replacement information.

The readout circuit 22 outputs the read redundant replacement information to the fuse bus 4 so as to transfer the information to the memory macro 3. In this embodiment, the readout circuit 22 outputs all bits of the redundant replacement information in parallel to the fuse bus 4. Thus, the readout circuit 22 reads out the redundant replacement information from the fuse set 21 in the same timing and then outputs the redundant replacement information at a time in the same timing. For example, if the data length of redundant replacement information is 15 bits, the data bus width of the fuse bus is also 15 bits. In this case, the macro ID is supplied to the first to fifth bits of the fuse bus 4, the first defective address is supplied to the sixth to tenth bits of the fuse bus 4, and the second defective address is supplied to the eleventh to fifteenth bits of the fuse bus 4.

Since the readout circuit 22 transfers the redundant replacement information in parallel, it can output the redundant replacement information read from the fuse set 21 as it is to the fuse bus 4 without parallel-serial conversion or the like.

Referring then to FIG. 4, the configuration of the memory macro of this embodiment is described herein. The memory macro 3 includes a memory cell 31, switching circuits 32a and 32b, a decoder 33, and a macro ID memory circuit 34.

The memory cell 31 is a memory cell array where a plurality of cells are arranged in a pattern. It has memory cores 311a and 311b and redundant circuits 312a and 312b. The memory cores 311a and 311b are memory areas and the redundant circuits 312a and 312b are redundant circuits to replace a defective cell.

In this example, the memory cell 31 is designed to be line-symmetric about a centerline, and the memory cores 311a and 311b are placed in the centerline side while the redundant circuits 312a and 213b are placed in both ends. However, the memory cell 31 may not be sectioned at the centerline but have one memory core and one redundant circuit or may have an arbitrary number of memory cores and redundant circuits. The same number of defective addresses of redundant replacement information as the redundant circuits are required.

The memory cell 31 has a plurality of word lines in the row or lateral direction and a plurality of bit lines in the column or longitudinal direction, which are arranged in a lattice pattern. A cell (memory element) is placed at the intersection between each word line and each bit line. The cell stores desired data when a predetermined voltage is supplied to the word line and the bit line from a driver, which is not shown.

In this example, the redundant circuits 312a and 312b are arranged in the column direction and therefore a defective cell is replaceable only in the column direction. The redundant circuits may be arranged in the row direction so as to allow replacement in the row direction, or they may be arranged so as to allow replacement in both the column and row directions.

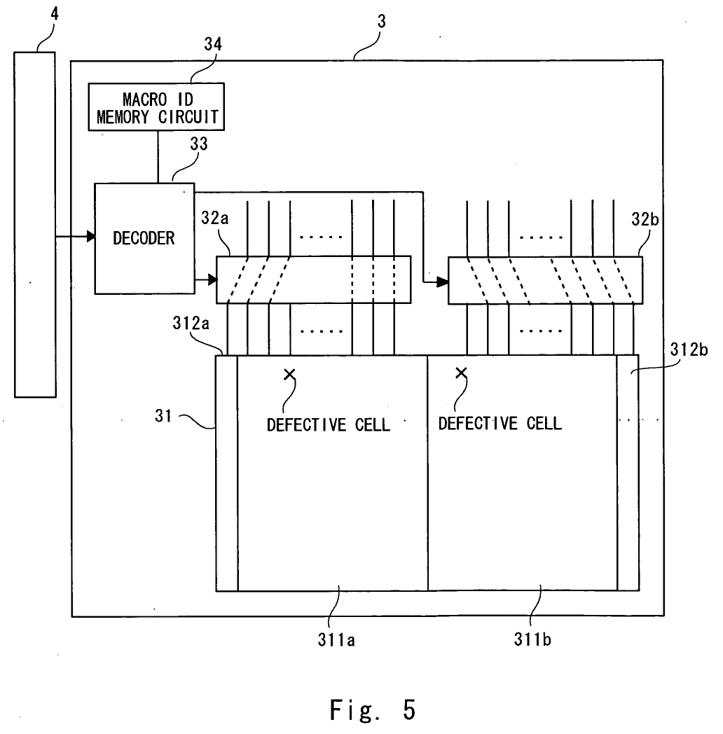

The switching circuits 32a and 32b switch the connection of the bit line between the memory cell 31 and the driver to save a defective cell. For example, the switching circuits 32a and 32b receive a switching signal corresponding to a defective address from the decoder 33 and switch the connection of the bit line of the defective cell according to the switching signal. The switching may simply switch only the bit lines connected to the defective cell so that they are connected to the redundant circuits 312a and 312b or may switch a plurality of bit lines as shown in FIG. 5. In FIG. 5, the bit lines which have been connected to the defective cell are shifted by 1 bit toward the redundant circuits 312a and 312b, that is, from the center line toward the both ends. At this time, not only the bit lines which have been connected to the defective cell but also all the bit lines which are located to the sides of the redundant circuits 312a and 312b from the defective cell are shifted by 1 bit for connection.

The macro ID memory circuit 34 is a memory circuit such as a latch circuit and stores micro ID. The macro ID is identification information for identifying the memory macros, and a different value is prestored for each memory macro.

The decoder 33 serves both as an input circuit to receive redundant replacement information and a circuit to analyze the redundant replacement information and convert it into a switching signal. The decoder 33 maybe composed of a comparator and a converter. The decoder 33 receives all bits of redundant replacement information from the fuse bus 4 and then analyzes and converts the redundant replacement information. For example, when the decoder 33 receives redundant replacement information from the fuse box 2 through the fuse bus 4, a macro ID in the redundant replacement information is input to a comparator and a defective address in the redundant replacement information is input to a converter. The comparator compares the macro ID contained in the redundant replacement information with the macro ID in the macro ID memory circuit 34. For example, the comparator compares the data of the first to fifth bits of the fuse bus 4 with the macro ID.

The converter converts the defective address according to the comparison result of the comparator. If the two macro IDs match, the converter converts the defective address into a switching signal and supplies the switching signal to the switching circuits 32a and 32b. For example, it converts the 5-bit data from the sixth to tenth bits of the fuse bus 4 as a first defective address and the 5-bit data from the eleventh to fifteenth bits of the fuse bus 4 as a second defective address into the switching signal. If, for example, the first defective address is the defective address of the memory core 311a, the switching signal converted from the first defective address is supplied to the switching circuit 32a, and if the second defective address is the defective address of the memory core 311b, the switching signal converted from the second defective address is supplied to the switching circuit 32b. If the two macro IDs do not match, the converter does not perform conversion and thus does not output any switching signal.

Since the redundant replacement information is transferred in parallel, the decoder 33 can perform data processing on the redundant replacement information that is supplied through the fuse bus 4 without serial-parallel conversion.

In this configuration, the integrated circuit device of this embodiment can reduce the number of fuse boxes to the degree that it can store a required number of pieces of redundant replacement information according to the probability of defect occurrence with respect to the total capacity of a plurality of memory macros, thereby reducing the circuit area. This effect is particularly significant if the integrated circuit device is a system LSI since it has a large number of memory macros having no defect and therefore it is possible to save a defect with a very small number of fuse boxes.

Further, since the integrated circuit device of this embodiment transfers all bits of redundant replacement information containing macro ID and defective addresses in parallel from the fuse box to the memory macro, it is possible to input and output the information necessary for replacement with the redundant circuit at a time without the need for conversion processing such as parallel-serial conversion. Furthermore, since it transfers redundant replacement information without changing data format, it eliminates the need for complex processing such as data compression and expansion, decomposition and composition. It is thereby possible to simplify the configuration of an input/output circuit (transfer circuit) to input and output the redundant replacement information and further increase the transfer speed of the redundant replacement information.

Simplification of the input/output circuit allows reduction of the circuit area of the fuse box and the memory macro and also allows easy extension when changing the number of memory macros or the like. A change in the number of memory macros merely requires a change in the number of macro ID and does not require any change in the input/output circuit, thus allowing easy design change. For example, increasing the number of memory macros simply needs to connect a memory macro with a different macro ID to the fuse bus used also for the existing memory macro. On the other hand, decreasing the number of memory macros simply needs to disconnect the memory macro from the fuse bus.

### Second Embodiment

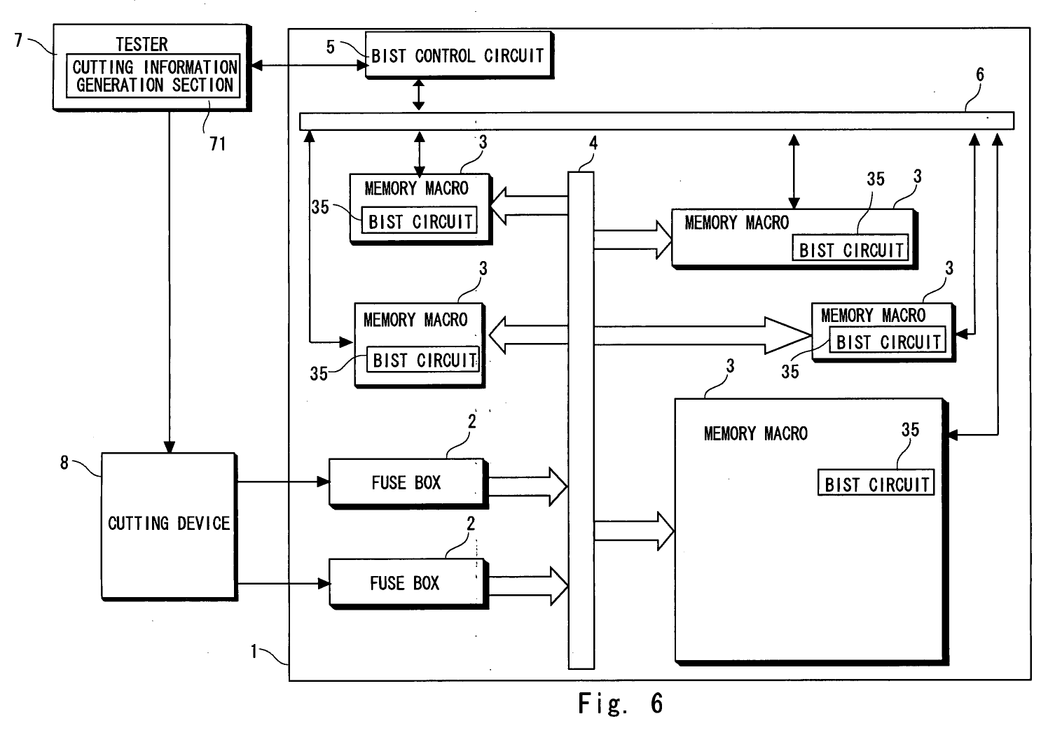

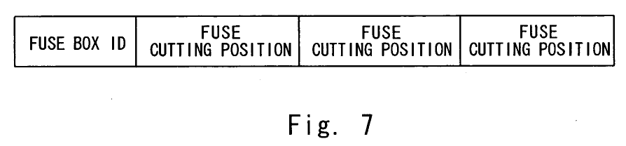

The integrated circuit device according a second embodiment of the present invention is described hereinafter with reference to FIGS. 6 and 7. The integrated circuit device. of this embodiment includes a BIST (Built In Self Test) circuit to test memory macros and cuts a fuse of a fuse box according to a test result of the BIST circuit.

Referring to FIG. 6, the configuration of the integrated circuit device of the second embodiment of the invention is described below. In FIG. 6, the same reference symbols as in FIG. 1 designate the same elements, which are not described herein.

As shown in FIG. 6, the integrated circuit device 1 has a BIST control circuit 5 and BIST circuits 35 that are placed in the memory macros 3, in addition to the components shown in FIG. 1. The BIST control circuit 5 and the BIST circuit 35 in each memory macro 3 are connected through a test bus 6, for example. Alternatively, the BIST control circuit 5 and each BIST circuit 35 may be connected directly without the test bus 6. Further alternatively, the BIST circuit 35 may be chain-connected, and some of the BIST circuits 35 and the BIST control circuit 5 may be connected.

Further, a tester 7 to test the integrated circuit device 1 and a cutting device 8 to cut a fuse are placed outside of the integrated circuit device 1. The tester 7 and the cutting device 8 may be separate units or one unit.

The BIST circuit 35 performs testing on the memory cell 31 of the memory macro 3. The BIST circuit 35 starts testing according to an instruction from the BIST control circuit 5. For example, the BIST circuit 35 generates a test pattern and supplies the test pattern to the memory cell 31. Then, it compares an output result of the memory cell 31 with an expected value to determine if the cell is defective or not. The BIST circuit 35 supplies the test result to the BIST control circuit 5. For example, the test result contains macro ID, a first defective address and a second defective address of the memory macro 3 just like the redundant replacement information of FIG. 3.

The BIST control circuit 5 controls the test operation of the BIST circuit 35 in each memory macro 3. For example, when the tester 7 switches the operation mode of the integrated circuit device 1 to a test mode or outputs a signal indicating test start, the BIST control circuit 5 supplies a signal indicating test start to each BIST circuit 35. Then, the BIST control circuit 5 receives test results from each BIST circuit 35 and supplies the rest result to the tester 7. The BIST control circuit 5 may exchange signals with the tester 7 directly or through a CPU core or the like.

The tester 7 is electrically connected to a test terminal or the like of the integrated circuit device 1 by probing and thereby exchanges signals indicating test start and test result with the BIST control circuit 5. The tester 7 has a cutting information generating section 71. When receiving a test result from the BIST control circuit 5, the cutting information generating section 71 converts the test result into fuse cutting information. Thus, the cutting information generating section 71 generates the fuse cutting information so as to store the test result into the fuse box 2 as redundant replacement information.

The fuse cutting information is the data as shown in FIG. 7, for example. The fuse cutting information contains fuse box ID and a plurality of fuse cutting positions. The fuse box ID is identification information to identify the fuse box 2. The fuse box ID may be identifier that is allocated to the fuse box 2 in advance. The fuse cutting position is the data to indicate the position of the fuse 211 to be cutout in the fuse box 2. For example, it may indicate a relative position such as the order in the longitudinal direction or the lateral direction in the fuse box 2 or an absolute position corresponding to the entire layout information of the integrated circuit device 1. If the fuse box can be specified by the fuse cutting position, the fuse cutting information may not contain the fuse box ID.

If the test result shows the presence of a defective cell, the cutting information generating section 71 of FIG. 6 determines the fuse box 2 to store the test result (redundant replacement information), receives the fuse box ID, and converts each of the macro ID, the first defective address and the second defective address contained in the test result into a fuse cutting position.

The cutting device 8 is a laser, for example, which cuts an optical fuse by a laser beam. It applies a laser beam to blow a fuse at the fuse cutting position according to the fuse cutting information generated by the cutting information generating section 71. Cutting the fuse allows the test result (redundant replacement information) to be stored in the fuse box 2. After cutting the fuse, the redundant replacement information of the fuse box 2 is transferred to the memory macro 3 and a defective cell is thereby replaced with a redundant circuit as is the case with the first embodiment.

In this configuration, the integrated circuit device of this embodiment generates the fuse cutting information based on the test result of the BIST circuit, thereby effectively cutting the fuse and storing redundant replacement information.

Though this embodiment tests the memory cell with the BIST circuit, it is feasible to test the memory cell by supplying a test pattern directly from the tester without the BIST circuit and generate fuse cutting information based on the test result.

### Third Embodiment

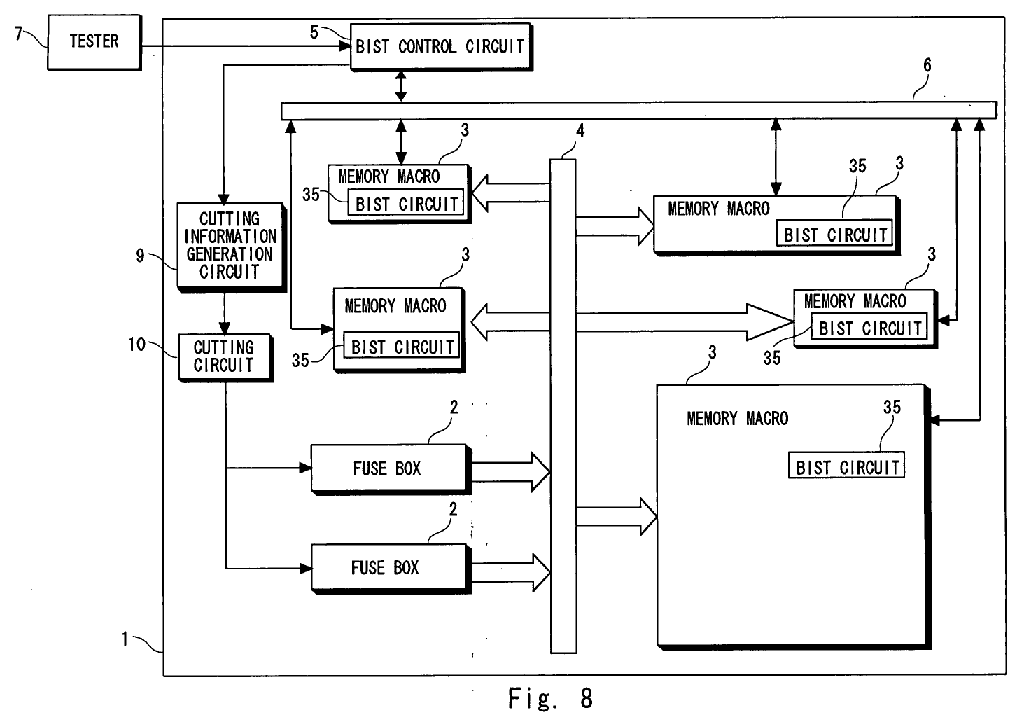

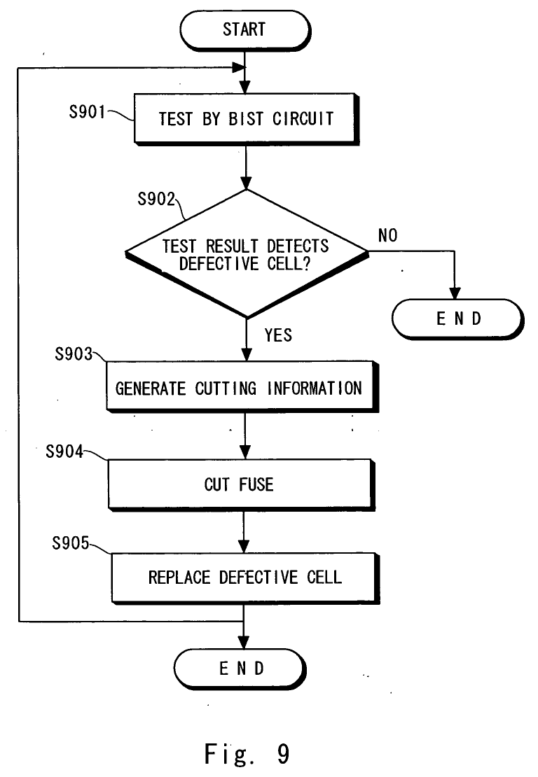

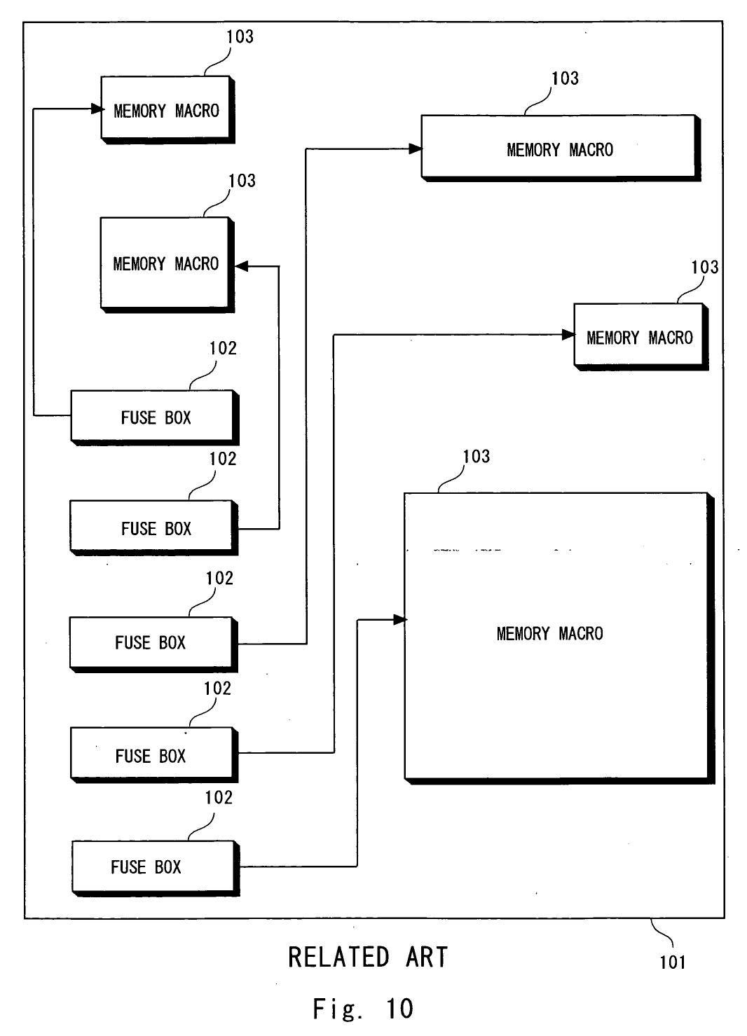

An integrated circuit device and a testing method according to a third embodiment of the present invention are described hereinafter with reference to FIGS. 8 and 9. The integrated circuit device of this embodiment includes a BIST circuit to test memory macros and cuts a fuse of a fuse box inside the integrated circuit device according to a test result of the BIST circuit.

Referring to FIG. 8, the configuration of the integrated circuit device of the third embodiment of the invention is described below. In FIG. 8, the same reference symbols as in FIGS. 1 and 6 designate the same elements, which are not described herein.

The integrated circuit device 1 includes a cutting information generation circuit 9 and a cutting circuit 10 in addition to the components shown in FIG. 6. This embodiment places the elements similar to the cutting information generating section 71 and the cutting device 8 of FIG. 6 inside the integrated circuit device 1.

The cutting information generation circuit 9 generates fuse cutting information of FIG. 7 like the cutting information generating section 71. The cutting information generation circuit 9 receives a test result from the BIST control circuit 5. The cutting information generation circuit 9 determines the fuse box 2 to store the test result (redundant replacement information), converts macro ID and defective addresses contained in the test result into fuse cut information, and supplies it to the cutting circuit 10.

The cutting circuit 10 is a circuit to cut a fuse like the cutting device 8. It cuts an electric fuse by outputting high current or high voltage, for example. The cutting circuit 10 cuts a fuse according to the fuse cutting information supplied from the cutting information generation circuit 9. The cutting circuit 10 is a write circuit to write redundant replacement information to the fuse box 2.

Referring then to the flowchart of FIG. 9, a testing method of the integrated circuit device of this embodiment is described herein. First, the BIST circuits 35 perform testing (S901). For example, when the tester 7 switches the operation mode of the integrated circuit device to a test mode, the BIST control circuit 5 instructs each BIST circuit 35 to start testing and each BIST circuit 35 thereby performs testing on each memory cell. Each BIST circuit 35 then supplies the test result to the BIST control circuit 5.

Next, the process determines if the test result shows the presence of a defective cell or not (S902). For example, the BIST control circuit 5 checks for the presence of a defective address with each test result supplied from each BIST circuit 35 to determine whether each memory macro 3 has a defective cell. The BIST control circuit 5 determines that a defective cell exists if a defective address exists and that no defective cell exists if no defective address exists.

If step S902 determines that no defective cell exists, the test ends. On the other hand, if it determines that a defective cell exists, fuse cutting information is generated (S903). For example, if a defective cell is detected, the BIST control circuit 5 supplies the test result to the cutting information generation circuit 9. Receiving the test result, the cutting information generation circuit 9 determines the fuse box 2 to store the test result (redundant replacement information). For example, if the fuse box 2 that already stores the test result exists, the cutting information generation circuit 9 selects another fuse box 2 and determines fuse box ID. Then, the cutting information generation circuit 9 converts the macro ID, the first defective address and the second defective address contained in the test result into fuse cutting information and supplies it to the cutting circuit 10.

Then, the process cuts a fuse (S904). For example, the cutting circuit 10 cuts a fuse according to the fuse cutting information that is supplied from the cutting information generation circuit 9. The cutting circuit 10 applies high current or high voltage to blow the fuse which is determined by the fuse box ID and the fuse cutting position contained in the fuse cutting information. If a plurality of test results indicating the presence of defective cells exist, the process performs steps S903 and S904 for each test result to cut the fuse of each fuse box.

After that, the process replaces a defective cell (S905) For example, the BIST control circuit 5 gives the CPU core notice of cutting the fuse corresponding to the defective cell. The CPU core sequentially supplies the signals indicating readout of redundant replacement information to the readout circuit 22 of each fuse box 2. The readout circuit 22 reads the redundant replacement information that is stored in the fuse 211 and supplies it to the memory macro 3 through the fuse bus 4. The redundant replacement information is transferred in parallel at substantially the same timing. Then, in the memory macro 3 whose macro ID matches the macro ID contained in the redundant replacement information, the defective cells corresponding to the first defective address and the second defective address of the redundant replacement information are replaced with a redundant circuit.

Then, in order to check the state after the replacement with the redundant circuit, the process repeats the processing from step S901. The steps may be repeated until a defective cell no longer exists or repeated a predetermined number of times. Further, the repetitive processing may be stopped upon exceeding a predetermined proportion defective. For example, if a larger number of defective cells than the number of cells replaceable with redundant circuits or a larger number of defective cells than the number of cells storable in the fuse box 2 are detected, the repetitive processing may be stopped.

In this configuration, the integrated circuit device of this embodiment can cut the fuse according to the test result of the BIST circuit and store the redundant replacement information inside the device. Further, it can replace a defective cell according to the redundant replacement information stored in the fuse box and perform testing again in the state after replacement. It is thereby possible to perform detection of a defective cell, replacement of the defective cell and assurance test after replacement automatically inside the integrated circuit device, thus achieving efficient testing.

Though the redundant replacement information is stored in the fuse of the fuse box in the above-described integrated circuit device, the present invention is not limited thereto, and it may be stored in nonvolatile memory such as EEPROM (Electronically Erasable and Programmable Read Only Memory).

It is apparent that the present invention is not limited to the above embodiment that may be modified and changed without departing from the scope and spirit of the invention.

What is claimed is:

1. An integrated circuit device comprising:
a plurality of memory macros each of which including a redundant circuit to replace a defective cell; and
a plurality of bits of nonvolatile memory elements storing redundant replacement information to replace a defective cell of a first memory macro selected from the plurality of memory macros with the redundant circuits,
wherein the redundant replacement information is transferred with a plurality of bits in parallel from the plurality of bits of nonvolatile memory elements to the plurality of memory macros.

2. The integrated circuit device according to claim 1, further comprising:
a bus connecting the plurality of memory macros and the plurality of bits of nonvolatile memory elements,
wherein a bus width of the bus equals data size of the redundant replacement information.

3. The integrated circuit device according to claim 1, wherein
the number of pieces of the redundant replacement information stored in the plurality of bits of nonvolatile memory elements is smaller than the number of the plurality of memory macros.

4. The integrated circuit device according to claim 1, wherein
the redundant replacement information contains memory macro identification information for identifying the first memory macro from the plurality of memory macros and defective address information for identifying the defective cell from a memory cell of the first memory macro.

5. The integrated circuit device according to claim 4, comprising:
a first and a second nonvolatile memory element groups including the plurality of bits of nonvolatile memory elements, wherein
the first nonvolatile memory element group stores the memory macro identification information, and
the second nonvolatile memory element group stores the defective address information.

6. The integrated circuit device according to claim 4, wherein
each of the plurality of memory macros replaces the defective cell according to the defective address contained in the redundant replacement information if the memory macro identification information contained in the redundant replacement information matches memory macro identification information of the memory macro.

7. The integrated circuit device according to claim 1, wherein
each of the plurality of memory macros has a memory cell array including a plurality of memory cells, and
a part of the plurality of memory cells included in the memory cell array is the redundant circuit.

8. The integrated circuit device according to claim 1, wherein
the plurality of bits of nonvolatile memory elements are a plurality of fuses.

9. The integrated circuit device according to claim 8, comprising:
a plurality of fuse boxes, each including the plurality of fuses and outputting the redundant replacement information according to cutting states of the plurality of fuses.

10. The integrated circuit device according to claim 9, wherein
each of the plurality of fuse boxes stores redundant replacement information corresponding to one of the plurality of memory macros, and
the number of the plurality of fuse boxes is smaller than the number of the plurality of memory macros.

11. The integrated circuit device according to claim 1, further comprising:
a test circuit testing memory cells of the plurality of memory macros to detect a defective cell; and
a write circuit writing the redundant replacement information based on a test result of the test circuit to the plurality of bits of nonvolatile memory elements.

12. The integrated circuit device according to claim 1, wherein
each of the plurality of memory macros has a Built In Self Test circuit testing a memory cell included in each memory macro to detect a defective cell.

13. The integrated circuit device according to claim 12, further comprising:
a control circuit controlling test operations of the Built In Self Test circuits and acquiring test results on the memory macros from the Built In Self Test circuits;
a generation circuit generating the redundant replacement information based on the test results; and
a write circuit writing the generated redundant replacement information to the plurality of bits of nonvolatile memory elements.

14. A testing method of an integrated circuit device having a memory macro, a test circuit, and a fuse box, the testing method comprising:
testing the memory macro by the test circuit;
storing redundant replacement information containing memory macro identification information for identifying the memory macro and a defective address for identifying a defective cell of the memory macro into the fuse box according to a test result; and
replacing the defective cell of the memory macro with a redundant circuit according to the redundant replacement information.
